(19) United States
(12) Patent Application Publication
(10) Pub. No.: US 2024/0105596 A1
(43) Pub. Date: Mar. 28, 2024

(54) INTEGRATED CIRCUIT DEVICES WITH ANGLED INTERCONNECTS

(71) Applicant: Intel Corporation, Santa Clara, CA (US)

(72) Inventors: Abhishek A. Sharma, Hillsboro, OR (US); Tahir Ghani, Portland, OR (US); Wilfred Gomes, Portland, OR (US); Anand S. Murthy, Portland, OR (US); Shem Ogadhoh, West Linn, OR (US); Pushkar Sharad Ranade, San Jose, CA (US); Sagar Suthram, Portland, OR (US); Elliot Tan, Portland, OR (US)

(73) Assignee: Intel Corporation, Santa Clara, CA (US)

(21) Appl. No.: 17/935,627

(22) Filed: Sep. 27, 2022

(51) Int. Cl. H01L 23/528; H01L 23/498

(52) U.S. Cl. CPC H01L 23/528; H01L 23/49838; H01L 24/16

(57) ABSTRACT

IC devices with angled interconnects are disclosed herein. An interconnect, specifically a trench or line interconnect, is referred to as an “angled interconnect” if the interconnect is neither perpendicular nor parallel to any edges of front or back faces of the support structure, or if the interconnect is not parallel or perpendicular to interconnect in another region of an interconnect layer. Angled interconnects may be used to decrease the area of pitch transition regions. Angled interconnects may also be used to decrease the area of pitch offset regions.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of devices and interconnects becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a top view of an example prior art interconnect layout with a pitch transition region.

FIG. 2 provides a top view of an example interconnect layout with a pitch transition region having angled interconnects, in accordance with some embodiments.

FIG. 3 provides a top view of a second example interconnect layout with a pitch transition region having angled interconnects, in accordance with some embodiments.

FIG. 4 provides a top view of an example interconnect layout with a pitch transition region having flared angled interconnects, in accordance with some embodiments.

FIG. 5 provides a top view of an example interconnect layout with two pitched-matched regions connected by angled interconnects, in accordance with some embodiments.

FIG. 6 provides a top view of a second example interconnect layout with two pitched-matched regions connected by angled interconnects, in accordance with some embodiments.

FIGS. 7A and 7B illustrate example perspective views and side views of dies formed over a wafer, according to some embodiments of the present disclosure.

FIG. 8 provides a first example cross-section of an IC device with interconnect layers that may include angled interconnects, in accordance with some embodiments.

FIG. 9 provides a second example cross-section of an IC device with interconnect layers that may include angled interconnects, in accordance with some embodiments.

FIG. 10 is a cross-sectional side view of an IC package that may include one or more angled interconnects in accordance with any of the embodiments disclosed herein.

FIGS. 11A and 11B are top views of, respectively, a wafer and dies that may include one or more angled interconnects in accordance with any of the embodiments disclosed herein.

FIG. 12 is a cross-sectional side view of an IC package that may include one or more angled interconnects in accordance with any of the embodiments disclosed herein.

FIG. 13 is a cross-sectional side view of an IC device assembly that may include one or more angled interconnects in accordance with any of the embodiments disclosed herein.

FIG. 14 is a block diagram of an example computing device that may include one or more angled interconnects in accordance with any of the embodiments disclosed herein.

### DETAILED DESCRIPTION

IC devices with angled interconnects, and related assemblies and methods, are disclosed herein. The devices, assemblies, and methods of this disclosure each have several innovative aspects, no single one of which is solely responsible for all the desirable attributes disclosed herein. Details of one or more implementations of the subject matter described in this specification are set forth in the description below and the accompanying drawings.

For purposes of illustrating IC devices with angled interconnects, proposed herein, it might be useful to first understand phenomena that may come into play in such arrangements. The following foundational information may be viewed as a basis from which the present disclosure may be properly explained. Such information is offered for purposes of explanation only and, accordingly, should not be construed in any way to limit the broad scope of the present disclosure and its potential applications.

An IC device includes various circuit elements, such as transistors and capacitors, coupled together by metal interconnects. The circuit elements and metal interconnects may be formed in different layers. In particular, one or more layers of an IC device in which transistors and other active IC components are implemented may be referred to as a “transistor layer” or “device layer”. One or more layers in which interconnects for providing electrical connectivity (e.g., in terms of signals and power) for various terminals of the transistors and/or other devices of the transistor layer of the IC device may be referred to as a “metallization layer” or “interconnect layer”. For example, the transistor layer may be a front-end-of-line (FEOL) layer, while the metallization layer may be a back-end-of-line (BEOL) layer of an IC device, but, in general, the transistor layer and the metallization layer may be provided in any layers of an IC device as long as they are in different planes (e.g., at different distances from) a support structure (e.g., a die, a chip, a substrate, a carrier substrate, or a package substrate) of the IC device, or some other reference plane.

Typically, an IC device includes a metallization stack, which is a collection of several metallization layers, stacked above one another, in which different interconnects are provided. The interconnects include electrically conductive trenches, also referred to as lines, which provide connectivity across the layer, and electrically conductive vias (or, simply, “vias”) providing electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided and may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” where the term “interconnect” may be used to describe any element formed of an electrically conductive material for providing electrical connectivity to/from one or more components associated with an IC or/and between various such components.

Trenches typically have elongated structures that extend primarily in one direction along a metallization layer. Typically, this direction is substantially parallel to the support structure on/in which a transistor resides and is either perpendicular or parallel to different edges of the support structure, in particular, being either perpendicular or parallel to different edges of the front face or the back face of the support structure.

In contrast to such conventional implementations, embodiments of the present disclosure provide IC devices with angled interconnects, and in particular, angled trenches. As used herein, an interconnect is referred to as an “angled interconnect” if the interconnect is neither perpendicular nor parallel to any edges of front or back faces of the support structure over which the transistor and the interconnect is implemented, e.g., if an angle between a projection of the interconnect onto a plane of the support structure and one or more of the edges of the support structure is between about 10 degrees and 80 degrees. Since, in geometry, not just one but two angles may be defined among any two lines crossing one another when the angles are defined as measured clockwise or counterclockwise with respect to one of the lines, the two such angles adding together to be 180 degrees, for the angled interconnects described herein the angles refer to the smaller of the two angles.

In some embodiments, a portion of interconnect structures in an interconnect layer may be arranged parallel to an edge of the support structure; this portion of interconnect structures is not considered angled. Angled interconnects may be coupled to the non-angled interconnect structures to provide additional routing options in an IC device. For example, angled interconnects may provide a pitch transition region between two interconnect regions of different pitches. Forming the pitch transition region from angled interconnects, as opposed to a zig-zag arrangement of non-angled interconnects, reduces the area consumed by the pitch transition region, and can improve density in the IC device. As another example, angled interconnects may connect to two interconnect regions of matching pitch. In this example, the angled interconnects can create an offset between the two interconnect regions, coupling an interconnect structure in the first region to an interconnect structure offset by one or two pitches in the second region.

The angled interconnects described herein may be included in various regions of an IC device or IC package. For example, angled interconnects may be formed in a metal layer on a front side or a back side of a die. As another example, in an IC package with multiple dies (e.g., one or more central processing units (CPUs), graphical processing units (GPUs), input/output (I/O) devices, etc.) coupled to a base die, angled interconnects may be included in any of the dies, including in the base die that connects to the dies supported by the base die. As another example, angled interconnects may be included in a full wafer device, including in a local interconnect layer interconnecting devices on a single die of the full wafer device, and/or in a global interconnect layer interconnecting multiple dies of the full wafer device.

In the following detailed description, various aspects of the illustrative implementations may be described using terms commonly employed by those skilled in the art to convey the substance of their work to others skilled in the art. For example, since, as is common in the field of FETs, designations of “source” and “drain” are often interchangeable, source and drain regions of a transistor may be referred to as first and second source or drain (S/D) region, where, in some embodiments, the first S/D region is a source region and the second S/D region is a drain region and, in other embodiments, this designation of source and drain region is reversed. Analogous applies to S/D contacts of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” “sulfide,” etc. refer to compounds containing, respectively, oxygen, carbon, nitrogen, sulfur, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art.

The term “interconnect” may refer to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias. The term “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The terms “over,” “under,” “between,” and “on” as used herein refer to a relative spatial position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

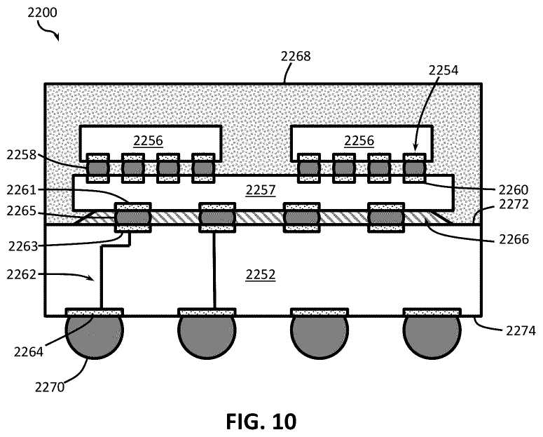

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, analogous elements designated in the present drawings with different letters, e.g., metal lines 210a, 210b, 210c, and 210d, may be collectively referred to together without the reference numerals after the dash, e.g., as “metal lines 210.” In order to not clutter the drawings, if multiple instances of certain elements are illustrated in a given drawing, only some of the elements may be labeled with a reference sign. A plurality of drawings with the same number and different letters may be referred to without the letters, e.g., FIGS. 10A-10B may be referred to as “FIG. 10.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with angled interconnects as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with angled interconnects as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

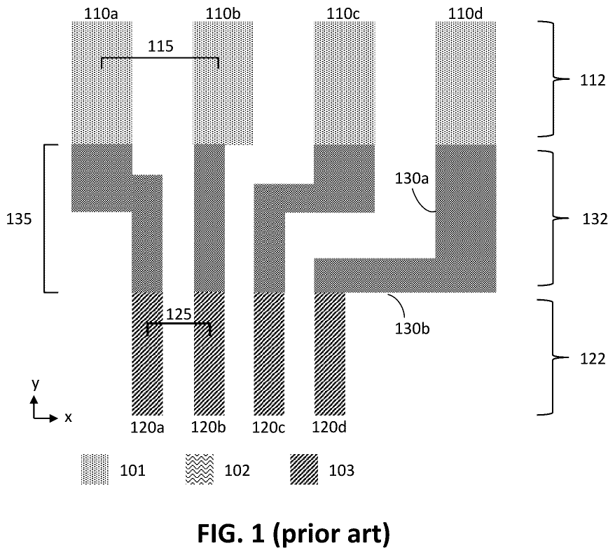

FIG. 1 provides a top view of an example prior art interconnect layout with a pitch transition region. The interconnect layout includes three interconnect regions 112, 122, and 132. The interconnect may be formed from any conductive material, such as copper. More generally, the interconnect may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, interconnect may include one or more electrically conductive alloys, oxides, or carbides of one or more metals.

In the example shown in FIG. 1, the interconnect material is represented by three different patterns 101, 102, and 103. The different patterns distinguish interconnect in different interconnect regions 112, 122, and 132, i.e., the interconnect region 112 includes the interconnect 101; the interconnect region 122 includes the interconnect 102; the interconnect region 132 includes the interconnect 103. The interconnects 101, 102, and 103 may comprise the same materials or different materials.

The interconnect region 112 includes interconnect 101 formed into metal lines 110 (or, more generally, conductive lines) having a pitch 115. The pitch refers to the center-to-center distance between closest adjacent structures, e.g., the illustrated pitch 115 is a center-to-center distance between the metal lines 110a and 110b. At least some of the other structures in the interconnect region 112 may have the same pitch 115; in this example, the metal lines 110a, 110b, 110c, and 110d are arranged at the pitch 115. The metal lines 110 extend in the y-direction in the example coordinate system shown in FIG. 1.

The interconnect region 122 includes interconnect 102 formed into metal lines 120 (or, more generally, conductive lines) having a pitch 125, e.g., the illustrated pitch 125 is a center-to-center distance between the metal lines 120a and 120b. The pitch 125 is less than the pitch 115. In this example, the pitch 125 is half the pitch 115. At least some of the other structures in the interconnect region 122 may have the same pitch 125; in this example, the metal lines 120a, 120b, 120c, and 120d are arranged at the pitch 125. The metal lines 120 extend in the y-direction in the example coordinate system shown in FIG. 1.

The interconnect region 132 is a pitch transition region between the two interconnect regions 112, 122 of different pitches 115, 125. The interconnect region 132 includes arrangement of metal lines to connect ones of the metal lines 110 to corresponding ones of the metal lines 120. The interconnect region includes metal lines that either extend in the x-direction or the y-direction in the example coordinate system shown in FIG. 1. For example, metal lines 130a and 130b connect the metal line 110d to the metal line 120d. The metal line 130a extends in the y-direction, and the metal line 130b extends in the x-direction.

The interconnect region 132 is typically designed to accommodate a minimum distance between adjacent metal lines, e.g., so that metal lines connecting 110d to 120d are not too close to the metal lines connecting 110c to 120c, for example. This results in a distance 135 between the interconnect region 112 and the interconnect region 122, also referred to as the height 135 of the pitch transition interconnect region 132. It is desirable to reduce the height 135 of the pitch transition region 132.

### Example Pitch Transition Regions with Angled Interconnects

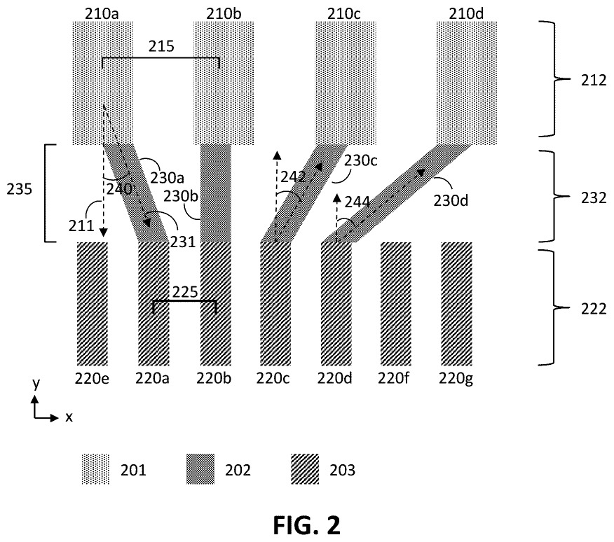

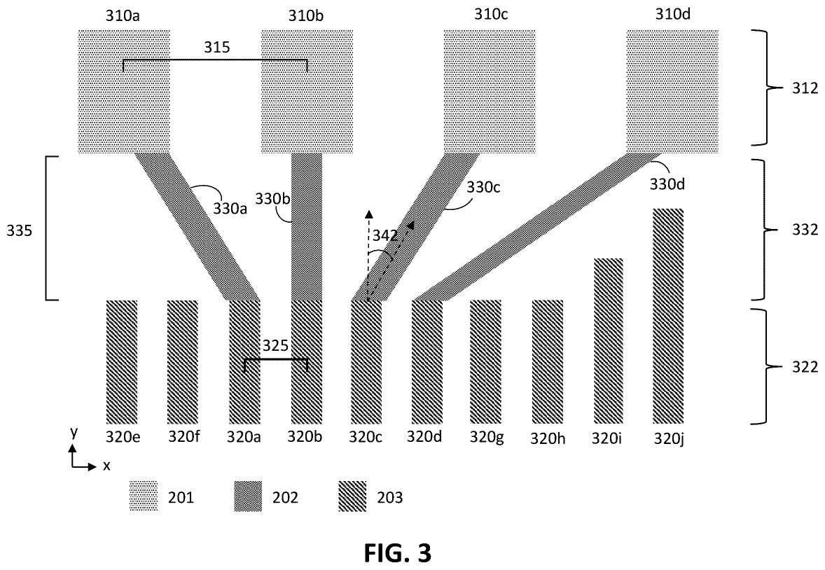

FIG. 2 provides a top view of an example interconnect layout with a pitch transition region having angled interconnects, in accordance with some embodiments. In the example shown in FIG. 2, the interconnect material is represented by three different patterns 201, 202, and 203. These patterns are also used in FIGS. 3-6, which provide additional example interconnect layouts with angled interconnects. As in FIG. 1, the different patterns distinguish interconnect in different interconnect regions. In FIG. 2, the interconnect region 212 includes the interconnect 201; the interconnect region 222 includes the interconnect 202; the interconnect region 232 includes the interconnect 203. The interconnects 201, 202, and 203 may comprise the same materials or different materials. The interconnects 201, 202, and 203 may include any of the interconnect materials described with respect to FIG. 1.

The interconnect region 212 includes interconnect 201 formed into metal lines 210 (or, more generally, conductive lines) having a pitch 215. The pitch 215 is the same as the pitch 115 in FIG. 1. The metal lines 210 extend in the y-direction in the example coordinate system shown in FIG. 2.

The interconnect region 222 includes interconnect 202 formed into metal lines 220 (or, more generally, conductive lines) having a pitch 225. The pitch 225 is less than the pitch 215. In this example, the pitch 225 is half the pitch 215. The pitch 215 is the same as the pitch 115 in FIG. 1. The metal lines 220 extend in the y-direction in the example coordinate system shown in FIG. 2. In addition, the metal lines 210 and 220 have different widths, i.e., dimensions in the x-direction in the coordinate system in FIG. 2. The metal lines 210 are wider than the metal lines 220, e.g., the metal lines 210 are approximately twice the width of the metal lines 220.

The interconnect region 232 is a pitch transition region between the two interconnect regions 212, 222 of different pitches 215, 225. The interconnect region 232 includes metal lines 230 to connect ones of the metal lines 210 to corresponding ones of the metal lines 320. For example, the metal line 230a connects the metal line 210a to the metal line 220a. In this example, the metal lines 230 have a width in the x-direction in the coordinate system shown that is approximately the width of the metal lines 220. At least a portion of the metal lines 230 are angled relative to the metal lines 210 and the metal lines 220. In particular, some of the metal lines 230 extend in directions neither parallel nor perpendicular to the metal lines 210 and 220. In a typical implementation, the edges of a support structure (e.g., a die) in or over which the interconnects are formed are aligned with the x-axis and y-axis in the coordinate system shown. Thus, at least some of the metal lines 230 are also angled relative to the edges of the support structure.

As an example, the metal line 230a extends in a direction 231 indicated by a dashed arrow through the center of the metal line 230a. The metal line 210a extends in the direction 211, which is parallel to the y-axis in the coordinate system shown. The direction 211 of the metal line 210a is at an angle 240 relative to the direction 231 of the angled metal line 230a.

Other metal lines 230 may be at different angles, or, in some cases, may not be angled relative to the metal lines 210 and 220 and/or relative to the edges of the support structure. For example, the metal line 230b extends in the y-direction, and is parallel to the metal lines 210b and 220b to which the metal line 230b is coupled. The metal line 230c is at an angle 242 relative to the metal line 220c. The metal line 230d is at an angle 244 relative to the metal line 220d. At least some of the metal lines 230 may be at an angle relative to the metal lines 210, 220 that is between 10 degrees and 80 degrees, e.g., between 20 degrees and 50 degrees, or within some other range.

As illustrated in FIG. 2, across the pitch transition region 232, different metal lines 230 may be at different angles relative to the other metal lines 210, 220. For example, the angle 244 is larger than the angle 242. In some embodiments, the angles of adjacent metal lines 230 relative to the metal lines 210, 220 may differ by at least 1 degree, by at least 2 degrees, by at least 5 degrees, or by at least 10 degrees. For example, the angles 242 and 244 may differ by at least one degree.

In some embodiments, the angles of adjacent metal lines 230 relative to the metal lines 210, 220 may differ by no more than a threshold amount, e.g., by no more than 45 degrees, no more than 30 degrees, or no more than 20 degrees. For example, the angles 242 and 244 may differ by no more than 30 degrees.

The pitch transition region 232 has a height 235, which is also a distance 235 between the interconnect region 212 and the interconnect region 222. As noted with respect to FIG. 1, reducing the height of the pitch transition region is desirable because it reduces the area consumed by the pitch transition region, and can improve density in the IC device. Using the angled metal lines 232 results in the height 235 being less than the height 135 in FIG. 1, for transition between similar interconnect regions (i.e., region 212 is similar to region 112, and region 222 is similar to region 122).

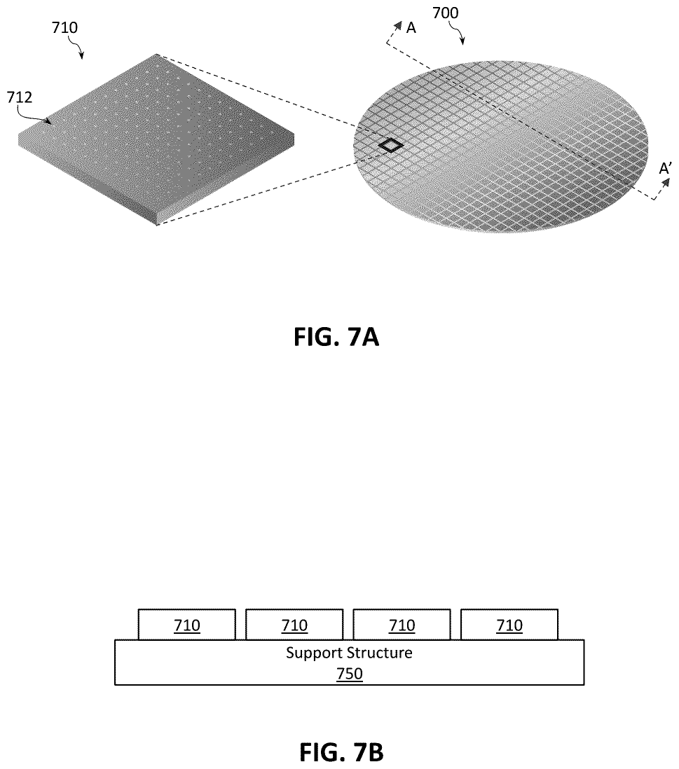

The interconnect layouts shown in FIG. 2-6 represents example layouts for an interconnect layer, or for a portion of an interconnect layer. An interconnect layer is one layer of an IC device. Other layers may include a device layer that includes transistors and/or other semiconductor devices; a memory layer that includes memory devices; other interconnect layers; etc. Furthermore, while the layout shown in FIG. 2 represents trenches extending in the x-y plane in the coordinate system shown, it should be understood that various portions of metal lines 210, 220, and/or 230 may be connected to vias to couple the metal lines to other conductive features above or below the metal lines 210, 220, 230 (i.e., at different positions along the z-direction). Several example devices that may include interconnect layers having layouts represented by FIGS. 2-6 are illustrated in FIGS. 7-10.

In the example shown in FIG. 2, the interconnect region 222 has metal lines 220e, 220f, and 220g which are not connected to other metal lines, e.g., the metal lines 220e, 220f, and 220g are not connected to metal lines in the pitch transition region 232. The metal lines 220e, 220f, and 220g are referred to as dummy metal lines or dummy lines. In the example shown in FIG. 2, the metal lines 220e, 220f, and 220g include the same conductive material as the other metal lines 220a, 220b, 220c, and 220d. In other embodiments, the dummy lines may include different materials, e.g., different conductive materials or non-conductive materials. Including the dummy lines 220e, 220f, and 220g may result in improved patterning of the interconnect region 232 and, more generally, of the metal layer illustrated in FIG. 2. The dummy lines 220e, 220f, and 220g may not be coupled to conductive features on other layers of a device including the interconnect represented in FIG. 2, e.g., the dummy lines 220e, 220f, and 220g may not be coupled to vias extending in the z-direction in the coordinate system shown in FIG. 2.

FIG. 3 provides a top view of a second example interconnect layout with a pitch transition region having angled interconnects, in accordance with some embodiments. The interconnect region 312 includes interconnect 201 formed into metal lines 310 (or, more generally, conductive lines) having a pitch 315. The metal lines 310 extend in the y-direction in the example coordinate system shown in FIG. 3. The interconnect region 322 includes interconnect 202 formed into metal lines 320 (or, more generally, conductive lines) having a pitch 325. The metal lines 320 extend in the y-direction in the example coordinate system shown in FIG. 3.

The pitch 325 is the same as the pitch 225 shown in FIG. 2. The pitch 315 is larger than the pitch 215 in FIG. 2, and larger than the pitch 325. In this example, the pitch 315 is three times the pitch 325. In addition, the metal lines 310 and 320 have different widths, i.e., dimensions in the x-direction in the coordinate system in FIG. 3. The metal lines 310 are wider than the metal lines 320, e.g., the metal lines 310 are approximately three times the width of the metal lines 320.

The interconnect region 332 is a pitch transition region between the two interconnect regions 312, 322 of different pitches 315, 325. The interconnect region 332 includes metal lines 330 to connect ones of the metal lines 310 to corresponding ones of the metal lines 320. For example, the metal line 330a connects the metal line 310a to the metal line 320a. In this example, the metal lines 330 have a width in the x-direction in the coordinate system shown that is approximately the width of the metal lines 320. At least a portion of the metal lines 330 are angled relative to the metal lines 310 and the metal lines 320. In particular, as described with respect to FIG. 2, some of the metal lines 330 extend in directions neither parallel nor perpendicular to the metal lines 310 and 320. In a typical implementation, the edges of a support structure (e.g., a die) in or over which the interconnects are formed are aligned with the x-axis and y-axis in the coordinate system shown. Thus, at least some of the metal lines 330 are also angled relative to the edges of the support structure.

As noted with respect to the metal lines 230 of FIG. 2, different ones of the metal lines 330 may be at different angles, or, in some cases, may not be angled relative to the metal lines 310 and 320 and/or relative to the edges of the support structure. For example, the metal line 330b extends in the y-direction, and is parallel to the metal lines 310b and 320b to which the metal line 330b is coupled. The metal line 330c is at an angle 342 relative to the metal line 320c. At least some of the metal lines 330 may be at an angle relative to the metal lines 310, 320 that is between 10 degrees and 80 degrees, e.g., between 20 degrees and 50 degrees, or within some other range. As in FIG. 2, across the pitch transition region 332, different metal lines 330 may be at different angles relative to the other metal lines 310, 320. In some embodiments, the angles of adjacent metal lines 330 relative to the metal lines 310, 320 may differ by at least 1 degree, by at least 2 degrees, by at least 5 degrees, or by at least 10 degrees. In some embodiments, the angles of adjacent metal lines 330 relative to the metal lines 310, 320 may differ by no more than a threshold amount, e.g., by no more than 45 degrees, no more than 30 degrees, or no more than 20 degrees.

FIGS. 2 and 3 generally illustrate that a pitch transition region with angled interconnects can be used to connect regions of various different pitches and widths, e.g., to connect one region (e.g., the region 222) to a region with double the pitch and width (e.g., the region 212), which is a 1:2 pitch ratio; or to connect one region (e.g., the region 322) to a region with three times the pitch and width (e.g., the region 312), which is a 1:3 pitch ratio. These examples are not limiting, and angled interconnects can be used to connect regions with different pitch ratios, e.g., 1:1.5, 1:2.5, 1:4, etc.

The pitch transition region 332 has a height 335, which is also a distance 335 between the interconnect region 312 and the interconnect region 322. The height 335 is larger than the height 235 in FIG. 2 to accommodate the larger change in pitch between the two regions 312 and 322. However, by using angled metal lines 330, the height 335 is less than the height of a pitch transition region formed using interconnects that extend only in the x-direction and y-direction.

The metal lines 320e, 320f, 320g, 320h, and 320i are dummy lines that are not connected to other metal lines, e.g., not connected to metal lines in the pitch transition region 332. While the metal lines 320e, 320f, 320g, 320h, and 320i are illustrated as including the same conductive material as the other metal lines 320a-320d, in other embodiments, the dummy lines may include different materials, e.g., different conductive materials or non-conductive materials. As described with respect to the dummy lines 220e, 220f, and 220g in FIG. 2, including the dummy lines 320e, 320f, 320g, 320h, and 320i may result in improved patterning of the interconnect region 332 and, more generally, of the metal layer illustrated in FIG. 3. The dummy lines 320e, 320f, 320g, 320h, and 320i may not be coupled to conductive features on other layers of a device including the interconnect represented in FIG. 3, e.g., the dummy lines 320e, 320f, 320g, 320h, and 320i may not be coupled to vias extending in the z-direction in the coordinate system shown in FIG. 3. In the example shown in FIG. 3, a portion of the dummy lines 320h and 320i extend above the interconnect region 320 and into the pitch transition region 330. This may improve patterning of the metal layer shown in FIG. 3, by not having a large gap into the pitch transition region 330.

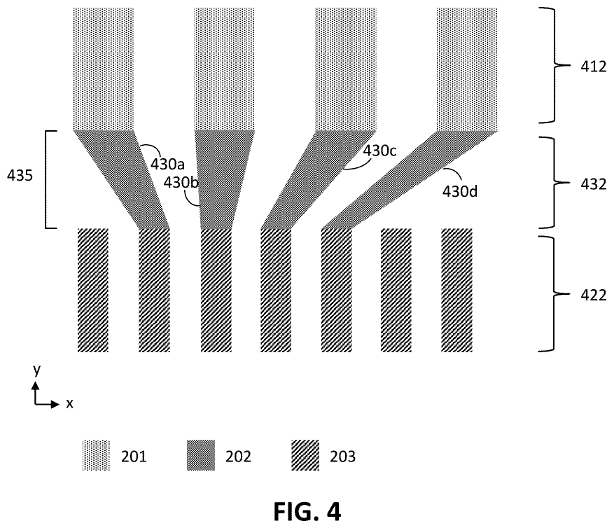

FIG. 4 provides a top view of an example interconnect layout with a pitch transition region having flared angled interconnects, in accordance with some embodiments. FIG. 4 includes an interconnect region 412, an interconnect region 422, and an interconnect region 432. The interconnect region 432 is pitch transition region. The interconnect region 412 is similar to the interconnect region 212 illustrated in FIG. 2, and the interconnect region 422 is similar to the interconnect region 222 illustrated in FIG. 2.

The pitch transition region 432 includes flared metal lines 430. In the example shown in FIG. 2, the metal lines 230 have a width in the x-direction in the coordinate system shown that is approximately the width of the metal lines 220. By contrast, in the example shown in FIG. 4, the metal lines 430 have a varying width that increases moving from the metal lines in the pitch transition region 422 to the metal lines in the pitch transition region 412. In this example, at the lower end of the pitch transition region 432, the metal lines 430 have a width in the x-direction that is approximately the width of the metal lines of the interconnect region 422, while at the upper end of the pitch transition region 432, the metal lines 430 have a width in the x-direction that is approximately the width of the metal lines of the interconnect region 412.

### Example Pitch Offset Regions with Angled Interconnects

In the examples shown in FIGS. 2-4, angled interconnects are used to connect two interconnect regions having metal lines at different pitches. In other examples, angled interconnects can be used to provide space-efficient connections between interconnect regions with matched pitch, e.g., to connect two regions with offset pitches.

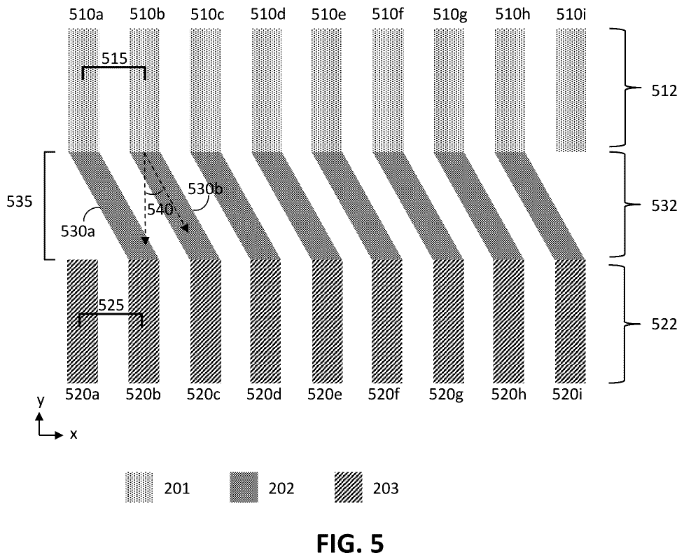

FIG. 5 provides a top view of an example interconnect layout with two pitched-matched regions connected by angled interconnects, in accordance with some embodiments. The interconnect region 512 includes interconnect 201 formed into metal lines 510 (or, more generally, conductive lines) having a pitch 515. The metal lines 510 extend in the y-direction in the example coordinate system shown in FIG. 5. The interconnect region 522 includes interconnect 202 formed into metal lines 520 (or, more generally, conductive lines) having a pitch 525. The metal lines 520 extend in the y-direction in the example coordinate system shown in FIG. 5. The pitch 515 is the same as the pitch 525. Thus, the regions 512 and 522 are pitch-matched regions. In addition, the metal lines 510 and 520 have a same width, i.e., a same dimension in the x-direction in the coordinate system in FIG. 5.

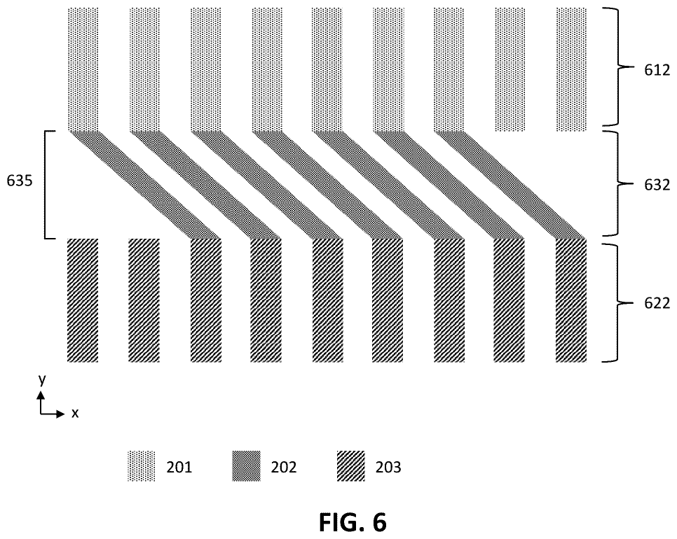

The interconnect region 532 is a pitch offset region between the two interconnect regions 512, 522. The pitch offset region 532 includes metal lines 530 to connect ones of the metal lines 510 to ones of the metal lines 520. The pitch offset region 532 couples metal lines in an offset manner. For example, the metal line 510a is aligned in the x-direction with metal line 520a. But, rather than coupling the metal line 510a to metal line 520a, the metal line 530a connects the metal line 510a to a metal line 520b which is offset by one pitch from the metal lines 510a and 520a. In other embodiments, a pitch offset region may couple metal lines to provide different pitch offsets, e.g., by two pitches, three pitches, four pitches, etc. FIG. 6 illustrates a pitch offset region that includes a two-pitch offset.

In this example, the metal lines 530 have a width in the x-direction in the coordinate system shown that is approximately the width of the metal lines 510 and 520. The metal lines 530 are angled relative to the metal lines 510 and the metal lines 520. In particular, the metal lines 530 extend in directions neither parallel nor perpendicular to the metal lines 510 and 520. In a typical implementation, the edges of a support structure (e.g., a die) in or over which the interconnects are formed are aligned with the x-axis and y-axis in the coordinate system shown. Thus, the metal lines 530 are also angled relative to the edges of the support structure.

In this example, each of the metal lines 530 has a same angle 540 relative to the metal lines 510 and 520. For example, the metal line 510b extends in the y-direction, and the metal line 530b is at an angle 540 relative to the metal line 510b. The angle 540 may be between 10 degrees and 80 degrees, e.g., between 20 degrees and 50 degrees, or within some other range.

The pitch offset region 532 has a height 535, which is also a distance 535 between the interconnect region 512 and the interconnect region 522. By using angled metal lines 530, the height 535 is less than the height of a pitch offset region formed using interconnects that extend only in the x-direction and y-direction.

The metal lines 520a and 510i are dummy lines that are not connected to other metal lines, e.g., not connected to metal lines in the pitch offset region 532. While the metal lines 520a and 510i are illustrated as including the same conductive material as the other metal lines 520 and 510, in other embodiments, the dummy lines may include different materials, e.g., different conductive materials or non-conductive materials. Including the dummy lines 520a and 510i may result in improved patterning of the interconnect regions 510 and 520 and, more generally, of the metal layer illustrated in FIG. 5.

FIG. 6 provides a top view of a second example interconnect layout with two pitched-matched regions connected by angled interconnects, in accordance with some embodiments. FIG. 6 includes an interconnect region 612, an interconnect region 622, and an interconnect region 632. The interconnect region 632 is pitch offset region. The interconnect region 612 is similar to the interconnect region 512 illustrated in FIG. 5, and the interconnect region 622 is similar to the interconnect region 522 illustrated in FIG. 5.

The pitch offset region 632 includes metal lines to connect ones of the metal lines in the interconnect region 612 to ones of the metal lines in the interconnect region 622. The pitch offset region 632 couples metal lines in an offset manner. In particular, the interconnect region 632 connects lines in the interconnect region 612 to ones of the metal lines in the interconnect region 622 that are offset by two pitches.

### Example Devices Having Angled Interconnects

As noted above, FIGS. 2-6 represent example layouts for an interconnect layer, or for a portion of an interconnect layer. Such interconnect layers may be included in different types of IC devices, and at various portions of such IC devices. Several example devices that may include interconnect layers having layouts represented by any of FIGS. 2-6 are illustrated in FIGS. 7-10.

FIGS. 7A and 7B illustrate example perspective views and side views of dies formed over a wafer, according to some embodiments of the present disclosure. The wafer 700 may be generally circular or approximately circular. The wafer 700 may include one or more angled interconnects as described herein.

The wafer 700 may be composed of semiconductor material and include multiple dies having IC structures formed on a surface of the wafer 700. One of the dies 710 is labelled and enlarged in FIG. 7A, but a plurality of similar dies are shown to be arranged in a grid-like manner across the wafer 700. Each of the dies of the wafer 700 may be a repeating unit of a semiconductor product that includes any suitable IC. The dies 710 may include semiconductor devices for implementing computing logic, e.g., transistors and/or capacitors. Individual dies 710 may further include circuitry for connecting these devices, e.g., interconnect circuitry that may include lines (or trenches) and vias. The interconnect circuitry is typically formed from conductive materials, and may be formed in one or more interconnect layers, also referred to as metal layers. Within a given die, the interconnect layers are referred to herein as local interconnect layers, meaning that the interconnect structures are local to a die 710, rather than extending between multiple dies. The semiconductor devices may be formed in one or more layers, which may be referred to as a logic layer or device layer. The dies 710 may be rectangular or square shaped. The dies 710 may be separated from each other by small spaces (e.g., less than 500 microns, or less than 200 microns) forming a grid, visible in FIG. 7A. These spaces are referred to as scribe lines, and typically do not include active circuitry.

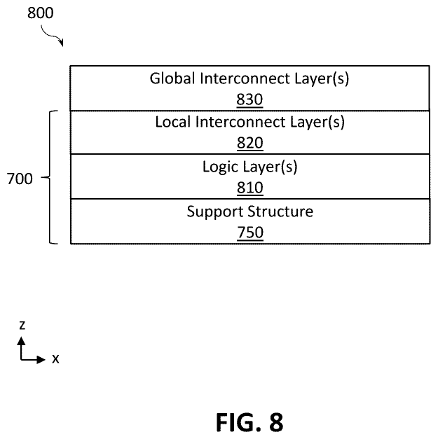

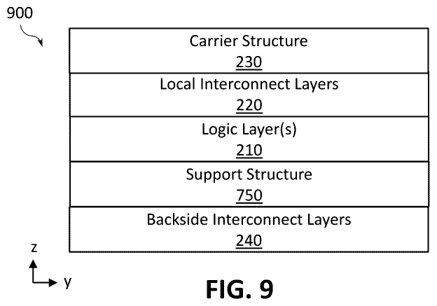

The enlarged die 710 of FIG. 7A further illustrates signal vias 712, only one of which is labeled in FIG. 7A with a reference numeral, but a plurality of which are shown in FIG. 7A to be arranged in a grid-like manner. The signal vias 712 may extend in or through the die 710 in order to communicate signals to, from, or between various IC components (e.g., transistors, resistors, capacitors, interconnects, etc.) of the die 710. For example, the signal vias 712 may communicate signals to/from/between transistors implementing compute logic if the die 710 is a compute die. At least a portion of the signal vias 712 may also connect to interconnect structures outside the compute die 710, e.g., as discussed in relation to FIGS. 8 and 9.

FIG. 7B illustrates an example cross-section of a wafer 700, taken through the plane AA′ illustrated in FIG. 7A. In this example, the wafer 700 includes a support structure 750 over which multiple dies 710 are formed. While four dies 710 are illustrated in FIG. 7B, it should be understood that more dies, or fewer dies, maybe included in the cross-section. In this example, the dies 710 are arranged over the support structure 750. For example, the dies 710 may be fabricated, tested, and mounted onto the support structure 750. Alternatively, the dies 710 may be built up over the support structure 750. In other embodiments, the dies 710 may be formed fully or partially in the support structure 750, rather than resting on top of the support structure 750.

The support structure 750 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which a full wafer device as described herein may be built falls within the spirit and scope of the present disclosure.

FIG. 8 provides a first example cross-section of an IC device with interconnect layers that may include angled interconnects, in accordance with some embodiments. The IC device 800 is a full wafer device 800 that includes the support structure 850 described in relation to FIG. 7. The full wafer device 800 further includes one or more logic layers 810 and one or more local interconnect layers 820. The support structure 750 has a front side and a back side, where the back side forms the back of the full wafer device 800. The logic layer 810 is formed over the front side of the support structure 750. The logic layers 810 may be computing logic layers that may include logic transistors and/or other logic devices. As described with respect to FIGS. 7A and 7B, the local interconnect layers 820 and logic layers 810 may be arranged in a plurality of dies (e.g., the dies 710). The local interconnect layers 820 connect to circuitry within a given die, i.e., each die 710 has a local interconnect structure in the local interconnect layers 820 coupled to logic in the logic layers 810. The local interconnect structures are not coupled between two or more dies. The logic layers 810 and local interconnect layers 820 may form a logic IC. In some embodiments, additional types of structures, such as memory devices, optical devices, passive circuitry, etc., may be included in the logic layers 810, local interconnect layers 820, and/or additional layers not depicted in FIG. 8. While the local interconnect layers 820 are depicted as being formed over the logic layers 810, in some embodiments, one or more local interconnect layers 820 may be formed below a logic layer 810 (e.g., between a logic layer 810 and the support structure 750). In some embodiments, one or more interconnect layers 820 may be interspersed between two logic layers 810. The support structure 750, logic layers 810, and local interconnect layers 820 form the wafer 700 shown in FIG. 7.

The full wafer device 800 further includes one or more global interconnect layers 830. The global interconnect layers 830 include interconnect structures that couple two or more dies together. In this example, the global interconnect layers 830 are formed over the local interconnect layers 820. Electrical signals, such as power and/or input/output (I/O) signals, may be routed to and/or from the logic layer 810 through the local interconnect layers 820 and the global interconnect layers 830. For example, electrically conductive features of the logic layer 810 (e.g., gates and source/drain (S/D) contacts of transistors in the logic layer 810) may be electrically coupled with the interconnect structures in the local interconnect layers 820. Interconnect structures in the local interconnect layers 820 may be electrically coupled with the interconnect structures in the global interconnect layers 830 to enable die-to-die communication in the full wafer device 800. The local interconnect layers 820 and global interconnect layers 830 may generally be referred to as back end layers, i.e., back end of line (BEOL) layers formed after the front end of line (FEOL) layers, which include the logic layer 810.

Interconnect structures in the local interconnect layers 820 and global interconnect layers 830 may be arranged in various layers to route electrical signals according to a wide variety of designs. In some embodiments, the interconnect structures may include trench structures (sometimes referred to as “lines”) and via structures (sometimes referred to as “holes”) filled with an electrically conductive material such as a metal. Trench structures may be arranged to route electrical signals in a direction of a plane that is substantially parallel with a surface of the support structure 750, while via structures may be arranged to route electrical signals in a direction of a plane that is substantially perpendicular to the surface of the support structure 750. Any of the interconnect structures in the local interconnect layers 820 and/or the global interconnect layers 830 may include angled interconnects, e.g., any of the angled interconnects illustrated in FIGS. 2-6.

In some embodiments, the global interconnect layers 830 may be fabricated in a separate process from the logic layers 810 and/or local interconnect layers 820. For example, in a first fabrication process, die-level structures including the logic layers 810 and local interconnect layers 820 are formed over the support structure 750 to produce a wafer with multiple dies, as illustrated in FIG. 7. In a second fabrication process, wafer-level structures, including the global interconnect layers 830, are formed over the wafer to produce the full wafer device 800.

In some embodiments, the die-level structures are first formed over a first support structure, and the dies are then singulated to provide discrete “chips” containing the die-level structures. The singulated dies may be tested, and accepted dies are assembled over the support structure 750 to produce the wafer 700. Then, the wafer-level structures, including the global interconnect layers 830, are formed over the reassembled dies to produce the full wafer device 800.

FIG. 9 provides a second example cross-section of an IC device with interconnect layers that may include angled interconnects, in accordance with some embodiments. The device 900 may be a full wafer device that may include the support structure 750 described in relation to FIG. 7. While the support structure 750 is included in the device 900 shown in FIG. 9, in other embodiments, the support structure 750 may be partly or fully removed during the manufacturing process. The device 900 further includes one or more logic layers 910 and one or more local interconnect layers 920, which are similar to the logic layers 810 and local interconnect layers 820 described above. As noted above, the support structure 750 has a front side and a back side, where the back side forms the back of the wafer. The logic layer 910 is formed over the front side of the support structure 750. The logic layer 910 likewise has a front side and a back side, where the front side is coupled to the local interconnect layers 920. A carrier structure 930 is coupled to the front side of the wafer, e.g., to a front side of the local interconnect layers 920. The carrier structure 930 may be similar to the support structure 750 described above.

More generally, the carrier structure 930 may be a wafer or another structure suitable for supporting the logic layers 910 and local interconnect layers 920. The carrier structure 930 may be bonded to the front side of the wafer using an adhesive material, heat, pressure, or a combination of techniques for bonding the carrier structure 930 to the wafer.

After the carrier structure 930 has been bonded to the wafer, some or all of the support structure 750 may be removed from the back side of the device. The support structure 750 may be removed by grinding and polishing, for example. In some embodiments, a portion of the support structure 750 is removed, while a portion of the support structure 750 remains attached to the logic layer 910.

After the support structure 750 has been fully or partially removed, backside interconnect layers 940 are fabricated on the back side of the device 900. The backside interconnect layers 940, logic layer(s) 910, and local interconnect layers 920 form a full wafer device 900. In the example shown in FIG. 9, the carrier structure 930 remains on the front of the full wafer device 900. In other embodiments, some or all of the carrier structure 930 is removed. For example, the backside interconnect layers 940 may be sufficiently thick to support the full wafer device 900, and the carrier structure 930 may be removed.

The backside interconnect layers 940 include interconnect structures that couple two or more dies together. These interconnect structures may be referred to as global interconnects, and the backside interconnect layers 940 may be referred to as global interconnect layers. In this example, the backside interconnect layers 940 are formed below the logic layer(s) 910. Electrical signals, such as power and/or input/output (I/O) signals, may be routed to and/or from the logic layer 910 through the backside interconnect layers 940. For example, electrically conductive features of the logic layer 910 (e.g., gates and source/drain (S/D) contacts of transistors in the logic layer 910) may be electrically coupled with the interconnect structures in the backside interconnect layers 940 to enable die-to-die communication in the full wafer device 900. In other embodiments, interconnect structures in the backside interconnect layers 940 may be coupled to interconnect structures in the local interconnect layers 920 by vias through the logic layer(s) 910, and the local interconnect layers 920 are in turn electrically coupled to the electrically conductive features of the logic layer 910. In addition to interconnect structures, the backside interconnect layers 940 may include one or more layers of active devices.

Any of the interconnect structures in the local interconnect layers 920 and/or the backside interconnect layers 940 may include angled interconnects, e.g., any of the angled interconnects illustrated in FIGS. 2-6.

In some embodiments, the backside interconnect layers 940 may be fabricated in a separate process from the logic layers 910 and/or local interconnect layers 920. For example, in a first fabrication process, die-level structures including the logic layers 910 and local interconnect layers 920 are formed over the support structure 750 to produce a wafer with multiple dies. In a second fabrication process, wafer-level structures, including the global interconnect layers 940, are formed on the back side to produce the full wafer device 900.

In some embodiments, the die-level structures are first formed over a first support structure, and the dies are then singulated to provide discrete “chips” containing the die-level structures. The singulated dies may be tested, and accepted dies are assembled over the support structure 750 to produce the wafer. Then, the wafer-level structures, including the backside interconnect layers 940, are formed on the back side of the reassembled dies to produce the full wafer device 900.

FIG. 10 is a cross-sectional side view of an IC package that may include one or more angled interconnects in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274. The conductive pathways in the package substrate 2252 may include angled interconnects, e.g., any of the angled metal lines shown in FIGS. 2-6.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 10 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 10 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

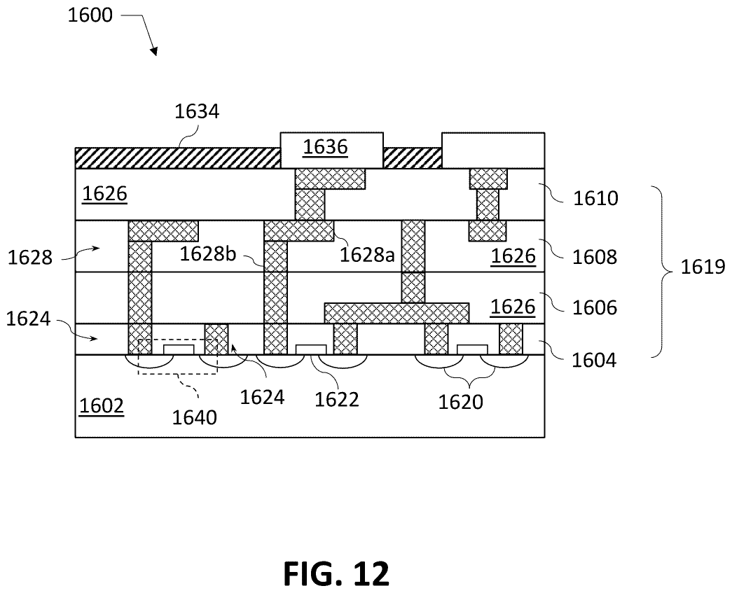

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 10 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein (e.g., may include any of the embodiments of the IC devices with angled interconnects as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high-bandwidth memory), including embedded memory dies as described herein. In some embodiments, any of the dies 2256 may include one or more IC devices with angled interconnects, e.g., as discussed above; in some embodiments, at least some of the dies 2256 may not include any IC devices with angled interconnects.

The IC package 2200 illustrated in FIG. 10 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 10, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

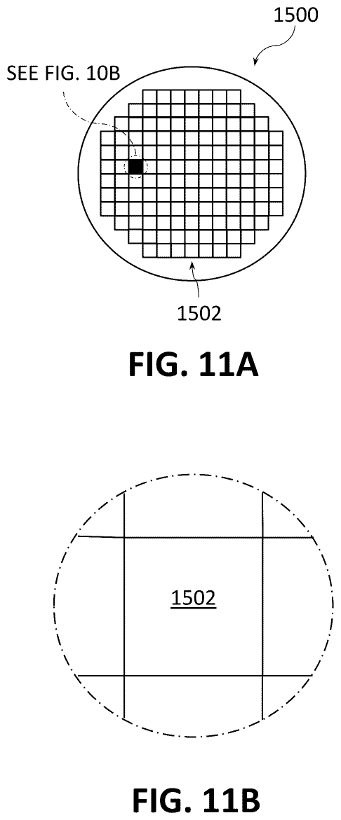

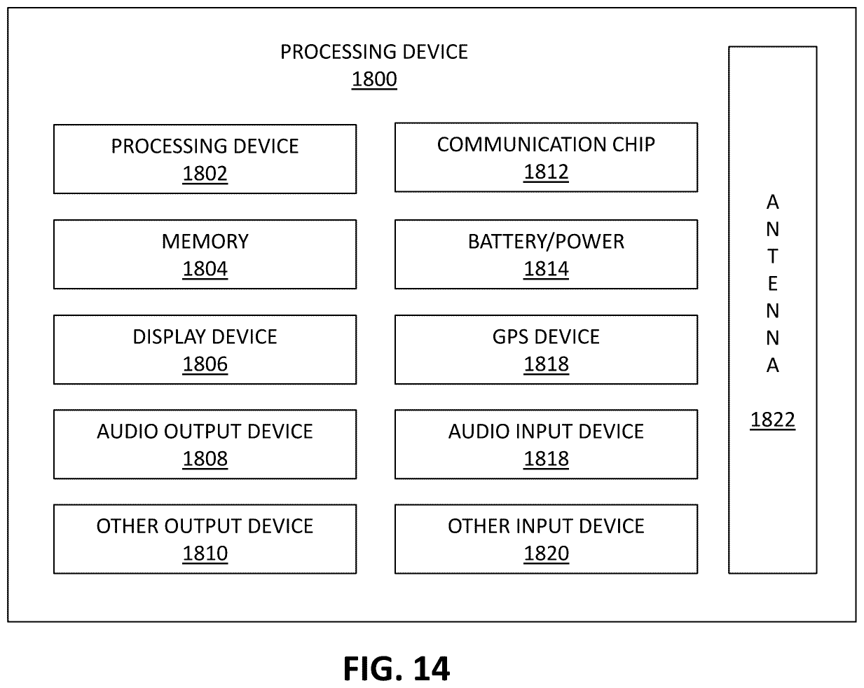

FIGS. 11A and 11B are top views of a wafer and dies that may include angled interconnects in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-9, or any further embodiments of the IC structures described herein). After the fabrication of the semiconductor product is complete (e.g., after manufacture of one or more IC structures included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more IC structures may take the form of the wafer 1500 (e.g., not singulated) or the form of the die 1502 (e.g., singulated). The die 1502 may include one or more transistors (e.g., one or more of the transistors 1640 of FIG. 12, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

FIG. 12 is a cross-sectional side view of an IC device 1600 that may include one or more angled interconnects in accordance with any of the embodiments disclosed herein. The IC device 1600 may be formed on a substrate 1602 (e.g., the wafer 1500 of FIG. 11A) and may be included in a die (e.g., the die 1502 of FIG. 11B). The substrate 1602 may be any substrate as described herein. The substrate 1602 may be part of a singulated die (e.g., the dies 1502 of FIG. 11B) or a wafer (e.g., the wafer 1500 of FIG. 11A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 12 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 12). Although a particular number of interconnect layers 1606-1610 is depicted in FIG. 12, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 12. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 12. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

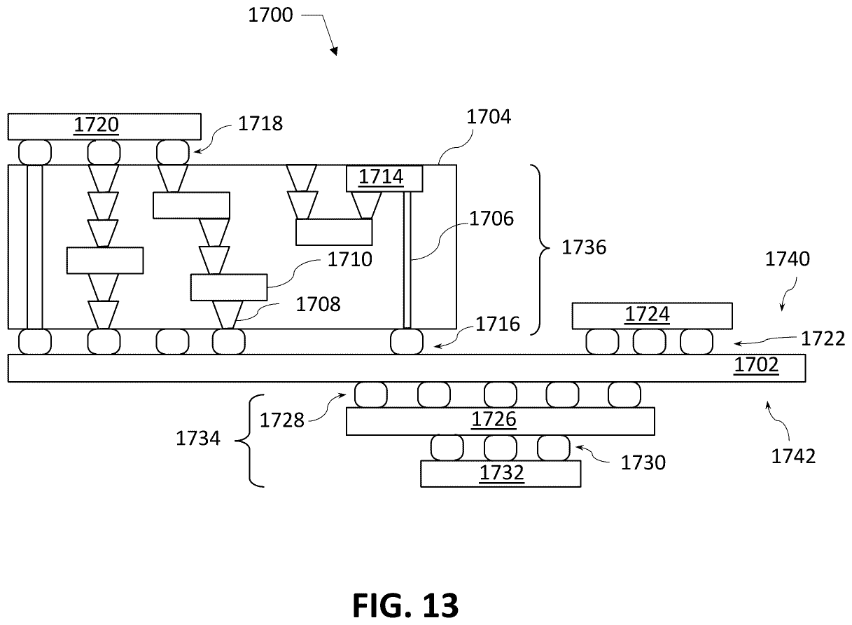

FIG. 13 is a cross-sectional side view of an IC device assembly 1700 that may include one or more angled interconnects in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 11B), an IC device (e.g., the IC device 1600 of FIG. 12), or any other suitable component. In some embodiments, the IC package 1720 include angled interconnects, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 13, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example computing device 1800 that may include angled interconnects in accordance with any of the embodiments disclosed herein. For example, any suitable ones of the components of the computing device 1800 may include angled interconnects as described herein. Any one or more of the components of the computing device 1800 may include, or be included in, an IC device 1600 (FIG. 12). Any one or more of the components of the computing device 1800 may include, or be included in, an IC device assembly 1700 (FIG. 13).

A number of components are illustrated in FIG. 14 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 14, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-M RAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

The following paragraphs provide various examples of the embodiments disclosed herein.

Example 1 provides a device including a first interconnect region including a first plurality of metal lines arranged at a first pitch and the metal lines extending in a first direction; a second interconnect region including a second plurality of metal lines arranged at a second pitch, the second pitch less than the first pitch; and an interconnect transition region including a plurality of angled metal lines, where one of the angled metal lines is coupled to one of the first plurality of metal lines and to one of the second plurality of metal lines, the one of the angled metal lines extends in a second direction, and an angle between the first direction and the second direction is between 10 degrees and 80 degrees.

Example 2 provides the device of example 1, the interconnect transition region including a second angled metal line coupled to a second of the first plurality of metal lines and a second of the second plurality of metal lines, the second angled metal line extending in a third direction, and a second angle between the first second and the third direction is different from the first angle.

Example 3 provides the device of example 2, where a difference between the first angle and the second angle is at least 1°.

Example 4 provides the device of example 2, where a difference between the first angle and the second angle is less than 30°.

Example 5 provides the device of any of the preceding examples, where the first pitch is at least twice the second pitch.

Example 6 provides the device of any of the preceding examples, further including a device layer having a plurality of semiconductor devices, where one of the semiconductor devices is coupled to one of the second plurality of metal lines.

Example 7 provides the device of example 6, where the second interconnect region includes a dummy metal line, the dummy metal line not coupled to a semiconductor device.

Example 8 provides the device of any of the preceding examples, where a second of the second plurality of metal lines is not coupled to an angled metal line.

Example 9 provides the device of any of the preceding examples, where the first plurality of metal lines have a first width, and the second plurality of metal lines have a second width, the second width less than the first width.

Example 10 provides the device of example 9, where the one of the angled metal line tapers from the first width to the second width.

Example 11 provides a device including a first interconnect region including a first plurality of metal lines arranged at a pitch and the metal lines extending in a first direction; a second interconnect region including a second plurality of metal lines arranged at the pitch, the second plurality of metal lines extending in the first direction; and a third interconnect region including a plurality of angled metal lines, where one of the angled metal lines is coupled to one of the first plurality of metal lines and to one of the second plurality of metal lines, the one of the angled metal lines extends in a second direction, and an angle between the first direction and the second direction is between 10 degrees and 80 degrees.

Example 12 provides the device of example 11, the third interconnect region including a second angled metal line coupled to a second of the first plurality of metal lines and a second of the second plurality of metal lines, the second angled metal line extending in the second direction.

Example 13 provides the device of example 11 or 12, where the angle between the first direction and the second direction is between 20 degrees and 50 degrees.

Example 14 provides the device of any of examples 11 through 13, where the one of the first plurality of metal lines and the one of the second plurality of metal lines are offset by the pitch.

Example 15 provides the device of any of examples 11 through 13, where the one of the first plurality of metal lines and the one of the second plurality of metal lines are offset by twice the pitch.

Example 16 provides the device of any of examples 11 through 15, further including a device layer having a plurality of semiconductor devices, where one of the semiconductor devices is coupled to one of the second plurality of metal lines.

Example 17 provides the device of any of examples 11 through 16, where a second of the second plurality of metal lines is not coupled to an angled metal line.

Example 18 provides the device of any of examples 11 through 17, where the first plurality of metal lines have a first width, and the second plurality of metal lines have a second width, the second width approximately equal to the first width.

Example 19 provides a device including a support structure having an edge; and an interconnect layer including a first interconnect portion extending in a first direction, the first direction parallel to the edge of the support structure; and a second interconnect portion coupled to the first interconnect portion, the second interconnect portion extending in a second direction, where an angle between the first direction and the second direction is between 10 degrees and 80 degrees.

Example 20 provides the device of example 19, where the interconnect layer is over the support structure, and the interconnect layer includes a via extending in a direction away from a back side of the device and toward the support structure.

Example 21 provides the device of example 19, where the interconnect layer is under the support structure, and the interconnect layer includes a via extending in a direction away from a front side of the device and towards the support structure.

Example 22 provides the device of any of examples 19 through 21, further including a plurality of dies coupled to the support structure, where the first interconnect portion is coupled to a first of the plurality of dies and a second of the plurality of dies.

Example 23 an IC package including a first die having an edge; a second die coupled to the first die; a third die coupled to the first die; and an interconnect layer in the first die, the interconnect layer including a first interconnect portion extending in a first direction, the first direction parallel to the edge of the first die; and a second interconnect portion coupled to the first interconnect portion, the second interconnect portion extending in a second direction, where an angle between the first direction and the second direction is between 10 degrees and 80 degrees.

Example 24 provides the IC package of example 23, further including an interposer coupled between the first die and the second die.

Example 25 provides the IC package of example 23 or 24, where the second die is a logic device.

Example 26 provides the IC package of any of examples 23 through 26, where the third die is an input/output device.

1. A device comprising:
a first interconnect region comprising a first plurality of metal lines arranged at a first pitch and the metal lines extending in a first direction;
a second interconnect region comprising a second plurality of metal lines arranged at a second pitch, the second pitch less than the first pitch; and
an interconnect transition region comprising a plurality of angled metal lines, wherein one of the angled metal lines is coupled to one of the first plurality of metal lines and to one of the second plurality of metal lines, the one of the angled metal lines extends in a second direction, and an angle between the first direction and the second direction is between 10 degrees and 80 degrees.

2. The device of claim 1, the interconnect transition region comprising a second angled metal line coupled to a second of the first plurality of metal lines and a second of the second plurality of metal lines, the second angled metal line extending in a third direction, and a second angle between the first second and the third direction is different from the first angle.

3. The device of claim 2, wherein a difference between the first angle and the second angle is at least 1°.

4. The device of claim 2, wherein a difference between the first angle and the second angle is less than 30°.

5. The device of claim 1, wherein the first pitch is at least twice the second pitch.

6. The device of claim 1, further comprising a device layer having a plurality of semiconductor devices, wherein one of the semiconductor devices is coupled to one of the second plurality of metal lines.

7. The device of claim 6, wherein the second interconnect region comprises a dummy metal line, the dummy metal line not coupled to a semiconductor device.

8. The device of claim 1, wherein a second of the second plurality of metal lines is not coupled to an angled metal line.

9. The device of claim 1, wherein the first plurality of metal lines have a first width, and the second plurality of metal lines have a second width, the second width less than the first width.

10. The device of claim 9, wherein the one of the angled metal line tapers from the first width to the second width.

11. A device comprising:
a first interconnect region comprising a first plurality of metal lines arranged at a pitch and the metal lines extending in a first direction;
a second interconnect region comprising a second plurality of metal lines arranged at the pitch, the second plurality of metal lines extending in the first direction; and
a third interconnect region comprising a plurality of angled metal lines, wherein one of the angled metal lines is coupled to one of the first plurality of metal lines and to one of the second plurality of metal lines, the one of the angled metal lines extends in a second direction, and an angle between the first direction and the second direction is between 10 degrees and 80 degrees.

12. The device of claim 11, the third interconnect region comprising a second angled metal line coupled to a second of the first plurality of metal lines and a second of the second plurality of metal lines, the second angled metal line extending in the second direction.

13. The device of claim 11, wherein the angle between the first direction and the second direction is between 20 degrees and 50 degrees.

14. The device of claim 11, wherein the one of the first plurality of metal lines and the one of the second plurality of metal lines are offset by the pitch.

15. The device of claim 11, wherein the one of the first plurality of metal lines and the one of the second plurality of metal lines are offset by twice the pitch.

16. The device of claim 11, further comprising a device layer having a plurality of semiconductor devices, wherein one of the semiconductor devices is coupled to one of the second plurality of metal lines.

17. An integrated circuit (IC) package comprising:
a first die having an edge;
a second die coupled to the first die;
a third die coupled to the first die; and
an interconnect layer in the first die, the interconnect layer comprising:
a first interconnect portion extending in a first direction, the first direction parallel to the edge of the first die; and
a second interconnect portion coupled to the first interconnect portion, the second interconnect portion extending in a second direction, wherein an angle between the first direction and the second direction is between 10 degrees and 80 degrees.

18. The IC package of claim 17, further comprising an interposer coupled between the first die and the second die.

19. The IC package of claim 17, wherein the second die is a logic device.

10. The IC package of claim 17, wherein the third die is an input/output device.
